(19) United States
(12) Patent Application Publication
(10) Pub. No.: US 2014/0152300 A1
(43) Pub. Date: Jun. 5, 2014

(54) STUD MAGNET DEVICE

(71) Applicants: Horward V. KEITH, III, Ontario, CA (US); Bryan Rivera, Ontario, CA (US)

(72) Inventors: Horward V. KEITH, III, Ontario, CA (US); Bryan Rivera, Ontario, CA (US)

(21) Appl. No.: 13/692,559

(22) Filed: Dec. 3, 2012

(51) Int. Cl. G01R 33/00

(52) U.S. Cl. CPC G01R 33/0047
USPC 324/259

(57) ABSTRACT

A magnetic stud sensor includes a handle portion and a body portion which together form an enclosure for loosely enclosing a magnet. The handle portion is adapted with indentations for a user's fingers and a projection for urging the magnet toward a wall. The body portion includes guides which, in connection with the projection, loosely hold the magnet near a planar portion of the body portion proximal a wall when the stud sensor is in use. As the stud sensor approaches a metal object behind a wall panel, the magnet is urged against and strikes the planar portion making an audible clicking or tapping sound.

This application claims the benefit of the filing date of provisional application No. 61/565,827, filed on Dec. 1, 2011.

### BACKGROUND

This invention relates to a stud finder (stud magnet device for locating a stud) behind a wall surface by detecting metal objects on the stud, including a nail or screw, or by detecting metal studs.

### SUMMARY

The stud sensor employs a magnet encased within a housing. The housing is defined by a handle portion serving as the top surface of the housing, and a body portion having a planar or slanted bottom surface, and walls. Three preferred embodiments, among others, are contemplated. In all three embodiments, the handle portion is a circular body with a plurality of curved indentures for finger gripping along the exterior circumference to make it ergonomic for a person to grasp and use the stud sensor.

The preferred embodiment of the housing is a hollow cylinder. The preferred embodiment of the magnet encased within the housing is also circular. The preferred material for the body portion and handle portion is plastic. It is also preferred that the planar bottom surface of the body portion has a smooth textile surface to slide easily and avoid scratching walls when the stud sensor is in use. It is understood that the preferred embodiments do not limit the scope of the invention, as such, the body portion may be rectangular and the handle portion and magnet may be square.

The bottom surface of the body portion is planar or flat and the handle portion contains an inner projection, preferably in the form of a cylinder that protrudes from under the surface of the top of the handle portion inside the body portion, and downward toward the magnet that is encased with the housing. The projection serves to hold, stop, or catch the magnet from falling down as it tips on its side allowing it to tip or slide back and forth so it has a gap at the inner bottom surface of the body portion to hold the magnet in the proper position.

A user may hold the stud magnet device by the handle portion and press the planar bottom of the body portion against a wall. When the user moves the stud sensor along the surface of a wall, due to the magnetic force generated by the magnet will make a tapping noise to guide the user to a metal stud, or a wooden stud with nails or screws in it. In certain embodiments, when the stud sensor is adjacent to a metal screw or nail, the magnet will be drawn immediately to the metal because of the shape and design of the bottom pins that hold, support and direct the magnet to tap on against the housing and a user will be able to sense and feel and hear it. The precise location of the stud is known when the stud magnet device can hold itself up against a wall without assistance from the user.

The second embodiment is similar to the first embodiment, except that the bottom surface of the body portion is slanted and the inner projection of the handle portion does not completely press the magnet against the inner bottom surface of the body portion. This means that the magnet sits loosely inside the body portion. When a user uses the second embodiment of the invention, the magnet will make a clicking or tapping sound by hitting against the bottom surface of the body portion as it approaches a metallic object behind the surface of a wall. The preferred angle of the slanted bottom surface is between two and twenty two degrees. Thus, in addition to the user sensing the magnetic force of the magnet being drawn to metal, the user will hear and feel the clicking or tapping sound and know the precise location of a wall stud.

Another embodiment of the invention is similar in that the bottom surface of the housing is planar. However, unlike the other contemplated embodiments, this embodiment will not stick to a wall. Instead, a smaller magnet contained within the body portion will activate a light housed in the handle portion , or activate a red dot contained within the handle portion. In the case of a red dot, the handle portion would has a window so users can see the red dot moving. In the case of a light, the handle portion or body portion will comprise a small battery to power the light.

### BRIEF DESCRIPTION OF THE FIGURES

FIG. 1 is a perspective view of a magnetic stud sensor according to the present invention.

FIG. 2 is a side cut-away view of a magnetic stud sensor according to the present invention.

### DESCRIPTION

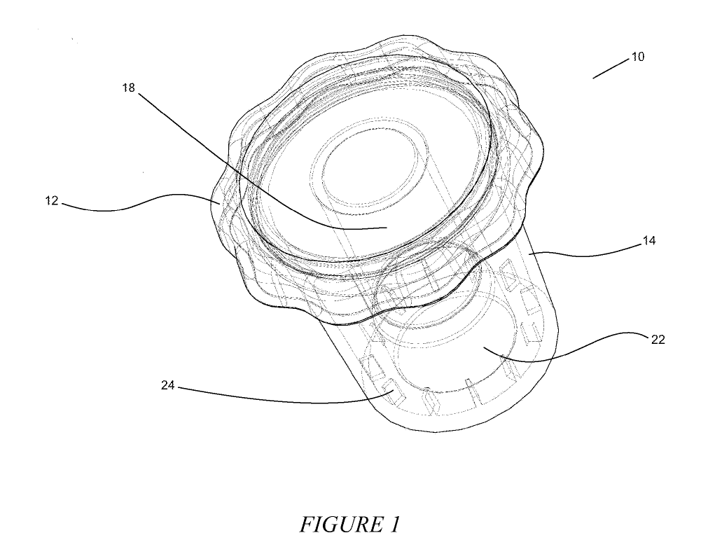

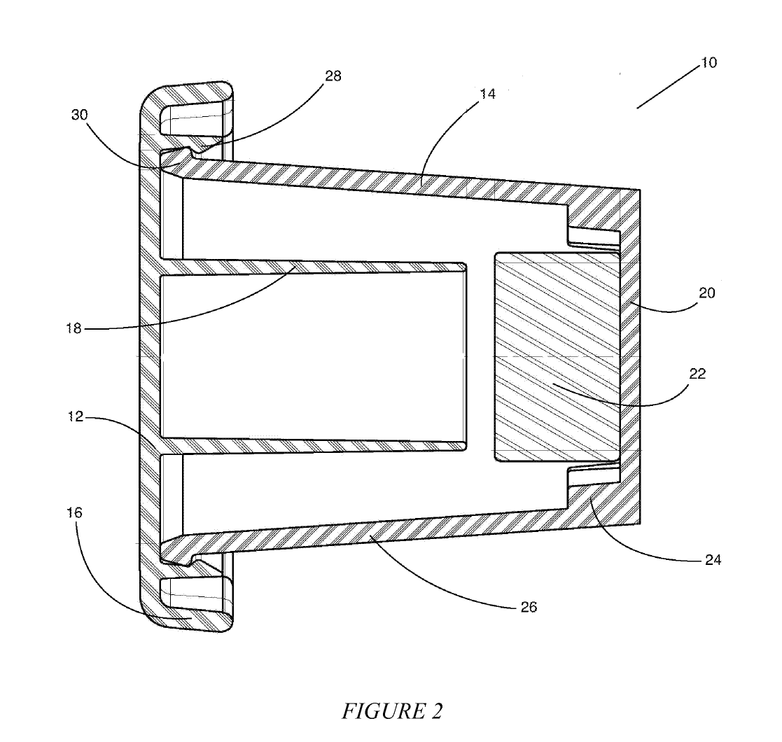

Referring to FIGS. 1 and 2, the magnetic stud sensor 10 comprises a handle portion 12 and a body portion 14. The handle portion 12 includes a lip 16 for holding the magnetic stud sensor 10 by a user. In one preferred embodiment the lip 16 is curved and indented to increase a user's grip. The handle portion 12 also includes a projection 18 which extends into the body portion 14. In one preferred embodiment the projection 18 is cylindrical to conform to the shape of the body portion 14.

The body portion 14 comprises a planar portion 20 adapted to adjoin a flat wall surface when sensing a stud. The handle portion 12 and body portion come together to house a magnet 22. The magnet 22 is preferably cylindrical and adapted to rest against the planar portion 20. The magnet 22 is loosely held in position by a series of guides 24 loosely surrounding the circumference of the magnet 22, the magnet 22 disposed between the planar portion 20 and the projection 18.

Importantly, while held in position, the magnet 22 is able to move within the confines of the stud sensor 10, enabling it to tap against the planar portion 20 as it attempts to engage a metallic object (not shown). To this end, the magnet may comprise a variety of compositions with magnetic properties, including molybdenum, which generate a strong magnetic field.

To facilitate manufacturing and construction of the stud sensor 10, the handle portion 12 includes a catch 28, and body portion 14 includes a lip 30. The catch 28 and lip 30 releasably engage each other enabling a user to disassemble the stud sensor 10 and replace the magnet 22 within. In other embodiments the modular nature of the handle portion 12 and body portion 14 enables a different body portion 14, such as one having a slanted planar portion 20 to engage the handle portion 12. This is useful when the stud sensor 10 is used on a high or difficult to reach portion of a wall.

In an embodiment wherein bottom surface of the housing is slanted and the projection 18 of the handle portion 12 does not completely press the magnet 22 against the planar portion 20 of the housing, the magnet 22 sits loosely inside the body portion 14 and will make a clicking or tapping sound by hitting against the planar portion 20 when it approaches a metallic object behind the surface of a wall (not shown). In such an embodiment, the preferred angle of the slanted planar portion 20 is between two and twenty two degrees.

Depending on the size of the magnet 22, the stud sensor 10 may or may not have the capability of holding fast to a wall when encountering a metallic object. For this reason it is contemplated that some embodiments of the invention will not stick to a wall. Instead, a less powerful or smaller magnet 22 will be contained within the body portion 14 will activate a light housed in the handle portion 12, or cause a red dot affixed to a movable member within the handle portion 12 to move. In such a case, the handle portion 12 would have a window so a user can see the red dot moving. In the case of a light, the handle portion 12 would comprise a small battery to power the light.

While the invention has been described according to various preferred embodiments, it is anticipated that various modifications and substitutions may be made thereto without departing from the spirit and scope of the invention. Accordingly it is to be understood that the invention has been described by way of illustration and not limitation.

What is claimed is:

1. A magnetic stud sensing device for sensing a wall stud comprising:
a handle portion adapted to be held in a user's hand;
a body portion having a planar portion adapted to engage a wall, and enclosing a magnet; and
an enclosure defined by the handle portion and body portion, wherein the enclosure is adapted to provide movement of the magnet.

2. The magnetic stud sensor of claim 1 wherein the handle portion is circular.

3. The magnetic stud sensor of claim 1 wherein the handle portion comprises indentations for a user's fingers.

4. The magnetic stud sensor of claim 1 wherein the handle portion comprises a projection.

5. The magnetic stud sensor of claim 4 wherein the projection is cylindrical.

6. The magnetic stud sensor of claim 1 wherein the body portion comprises a smooth planar portion for engaging a wall.

7. The magnetic stud sensor of claim 6 wherein the planar portion is slanted relative to the handle portion and body portion.

8. The magnetic stud sensor of claim 1 wherein the body portion comprises guides adapted to loosely confine the magnet.

9. The magnetic stud sensor of claim 1 wherein the handle portion and body portion comprise a mechanism for releasing the handle portion from the body portion. w

10. A magnetic stud sensing device for sensing a wall stud comprising:
a handle portion having a circular hand grip, including indentations to accommodate a user's fingers and a projection extending from the hand grip;
a cylindrical body portion having an opening adapted to be covered by the handle portion, a planar portion adapted to engage a wall, and guides adapted for loosely enclosing a magnet; and
wherein the magnet is loosely bound by the guides and projection, such that when the magnet encounters a magnetic object, it strikes the planar portion, making an audible sound.
